(19) United States
(12) Patent Application Publication
(10) Pub. No.: US 2025/0202455 A1
(43) Pub. Date: Jun. 19, 2025

(54) Film Bulk Acoustic Resonator and Manufacturing Method Therefor

(71) Applicant: Wuhan MEMSonics Technologies Co.,Ltd., Wuhan (CN)

(72) Inventors: Yao CAI, Wuhan (CN); Jie ZHOU, Wuhan (CN); Zhipeng DING, Wuhan (CN); Xiyu GU, Wuhan (CN); Kang YI, Wuhan (CN); Cong YU, Wuhan (CN); Xike LI, Wuhan (CN); Biao FU, Wuhan (CN); Chengliang SUN, Wuhan (CN); Bowoon SOON, Wuhan (CN)

(73) Assignee: Wuhan MEMSonics Technologies Co.,Ltd., Wuhan (CN)

(21) Appl. No.: 18/951,269

(22) Filed: Nov. 18, 2024

(30) Foreign Application Priority Data
Dec. 19, 2023 (CN) 202311763257.8

(51) Int. Cl. H03H 9/17; H03H 3/02; H03H 9/13

(52) U.S. Cl. CPC H03H 9/173; H03H 3/02; H03H 9/13; H03H 9/176; H03H 2003/021

(57) ABSTRACT

A film bulk acoustic resonator and a manufacturing method therefor are provided. The film bulk acoustic resonator includes: a substrate, and a lower electrode, a piezoelectric layer, electrode frame layers and an upper electrode sequentially stacked on the substrate; wherein a cavity is formed between the substrate and the lower electrode, a Q-increasing structure is formed by the lower electrode in a vertical projection range of the cavity, and a first air wing and a first air bridge are formed between the upper electrode and the piezoelectric layer.

### TECHNICAL FIELD

The present disclosure relates to the technical field of radio frequency filters, and in particular, to a film bulk acoustic resonator and a manufacturing method therefor.

### BACKGROUND

A radio frequency filter is a core component applied to a radio frequency front end in the field of wireless communications, and a film bulk acoustic resonator is a key and basic unit for constituting the radio frequency filter. A working principle of the film bulk acoustic resonator is: a radio frequency electrical signal is applied by an upper electrode and a lower electrode, and the electrical signal is converted into high-frequency vibration of a film by utilizing an inverse piezoelectric effect of a piezoelectric material, so as to generate an acoustic wave signal.

A quality factor (Q value) is one of main parameters characterizing the performance of the film bulk acoustic resonator, and represents the energy attenuation efficiency. The higher the quality factor, the higher the energy conversion efficiency of the device, and the smaller the loss of the film bulk acoustic resonator device. At present, the means for increasing the Q value of the resonator is mainly to add a frame structure, an air wing structure and an air bridge structure to the upper electrode. These structures have currently become conventional means for increasing the Q value, but the current means are limited in further increasing the Q value.

### SUMMARY

According to one aspect of embodiments of the present disclosure, provided is a film bulk acoustic resonator, comprising: a substrate, and a lower electrode, a piezoelectric layer, electrode frame layers and an upper electrode sequentially stacked on the substrate; wherein a cavity is formed between the substrate and the lower electrode, Q-increasing structure is formed by the lower electrode in a vertical projection range of the cavity, and a first air wing and a first air bridge are formed between the upper electrode and the piezoelectric layer.

Optionally, the Q-increasing structure includes at least one thickened layer of the lower electrode, and the at least one thickened layer is on a side of close to the cavity.

Optionally, the lower electrode has a first electrode area and a second electrode area connected by a transition electrode area to form a layered structure having a height difference; the transition electrode area and the first electrode area are both located at a position of the cavity.

Optionally, the at least one thickened layer is located on a surface of the first electrode area and protrudes towards a direction of the cavity.

Optionally, there are two thickened layers, which are located at the first electrode area at an interval.

Optionally, the at least one thickened layer is continuous annular structures or discontinuous block structures.

Optionally, a width of the at least one thickened layer is the same as or different from a width of the electrode frame layer.

Optionally, the Q-increasing structure includes a second air wing and a second air bridge formed between the lower electrode and the piezoelectric layer, wherein in a stacking direction, the second air wing corresponds to the first air bridge, and the second air bridge corresponds to the first air wing; and the second air wing and the second air bridge are located at the first electrode area.

Optionally, the lower electrode at a position corresponding to the cavity and the piezoelectric layer at a position corresponding to the cavity form a protrusion, and the electrode frame layers are located on the protrusion of the piezoelectric layer; and the first air wing and the first air bridge both correspond to the protrusion of the piezoelectric layer, and the Q-increasing structure is located on the protrusion of the lower electrode.

Optionally, the lower electrode does not completely cover the substrate; and the upper electrode does not completely cover the piezoelectric layer.

Optionally, the protrusion is a trapezoid protrusion.

Optionally, an area enclosed by projection boundaries of the upper electrode, the lower electrode and the piezoelectric layer is an active area, and outer boundaries of the thickened layers exceed the active area.

Optionally, there are two electrode frame layers, the upper electrode at a position of one electrode frame layer and the piezoelectric layer form the first air bridge, and the upper electrode at a position of the other electrode frame layer and the piezoelectric layer form the first air wing.

Optionally, a material of the lower electrode includes at least one of Mo, Au, Al, Cu, Ti and Wu, and the piezoelectric layer includes at least one of AlN, PZT, ZnO, LiNbO₃ and LiTaO₃.

According to another aspect of embodiments of the present disclosure, provided is a manufacturing method for a film bulk acoustic resonator, the method being used for manufacturing the film bulk acoustic resonator according to claim 1, wherein the method includes: providing a substrate, and etching the substrate to form a cavity; depositing a lower electrode on the substrate provided with the cavity, so that the lower electrode covers a part of the substrate, and forming a Q-increasing structure in a vertical projection range of the lower electrode on the cavity; and sequentially forming a piezoelectric layer, at least one electrode frame layer and an upper electrode on the lower electrode, so as to form a first air bridge and a first air wing between the upper electrode and the piezoelectric layer.

Optionally, wherein providing the substrate, and etching the substrate to form the cavity, include: etching the substrate to form a first cavity structure; filling a first sacrificial layer in the first cavity structure; and etching the first sacrificial layer to form two second cavity structures.

Optionally, wherein depositing the lower electrode on the substrate provided with the cavity, so that the lower electrode covers the part of the substrate, and forming the Q-increasing structure in the vertical projection range of the lower electrode on the cavity, include: depositing the lower electrode on the substrate provided with the second cavity structures, so that the lower electrode covers one end of the substrate up to the second cavity structures, and fills the second cavity structures, so as to form at least one thickened layer in at least one of the second cavity structures.

Optionally, wherein depositing the lower electrode on the substrate provided with the cavity, so that the lower electrode covers the part of the substrate, and forming the Q-increasing structure in the vertical projection range of the lower electrode on the cavity, includes: filling the second cavity structures with Q-increasing materials, so that the Q-increasing materials fill the second cavity structures flush; depositing upper electrode first sacrificial layers on the Q-increasing materials to form a second air wing and a second air bridge at the upper electrode first sacrificial layers; and depositing the lower electrode on the substrate, so that the lower electrode covers one end of the substrate up to the first sacrificial layer, and exposing the upper electrode first sacrificial layers.

Optionally, wherein sequentially forming the piezoelectric layer, the at least one electrode frame layer and the upper electrode on the lower electrode, so as to form a first air bridge and a first air wing between the upper electrode and the piezoelectric layer, includes: depositing the piezoelectric layer on the lower electrode, so that the piezoelectric layer completely covers the lower electrode and the substrate, and the piezoelectric layer protrudes at a position corresponding to the first cavity structure; depositing the electrode frame layers at positions of the protruding piezoelectric layer which correspond to the second cavity structures; depositing upper electrode second sacrificial layers at positions corresponding to the electrode frame layers, so that the upper electrode second sacrificial layers cover a part of the electrode frame layers and a part of the piezoelectric layer adjacent to the electrode frame layers; and depositing the upper electrode on the piezoelectric layer, so that the upper electrode covers an other end of the piezoelectric layer up to the protruding piezoelectric layer, the upper electrode second sacrificial layers, and the electrode frame layers.

Optionally, wherein sequentially forming the piezoelectric layer, the at least one electrode frame layer and the upper electrode on the lower electrode, so as to form a first air bridge and a first air wing between the upper electrode and the piezoelectric layer, the method further includes: releasing the first sacrificial layer, the upper electrode first sacrificial layers, and the upper electrode second sacrificial layers.

### BRIEF DESCRIPTION OF THE DRAWINGS

In order to illustrate technical solutions of embodiments of the present disclosure more clearly, hereinafter, accompanying drawings requiring to be used in the embodiments of the present disclosure will be briefly introduced. It should be understood that the following accompanying drawings only illustrate certain embodiments of the present disclosure, and therefore shall not be considered as limiting the scope. For a person of ordinary skill in the art, other related accompanying drawings can also be obtained according to these accompany drawings without any inventive effort.

FIG. 1 is a schematic structural diagram of Example I of a film bulk acoustic resonator provided according to the present embodiment;

FIG. 2 is a schematic structural diagram of Example II of a film bulk acoustic resonator provided according to the present embodiment;

FIGS. 3-12 are schematic diagrams of a manufacturing process of Example I of a film bulk acoustic resonator provided according to the present embodiment;

FIGS. 13-24 are schematic diagrams of a manufacturing process of Example II of a film bulk acoustic resonator provided according to the present embodiment; and

FIG. 25 shows simulation curves of film bulk acoustic resonators provided according to the present embodiment.

### DETAILED DESCRIPTION OF THE EMBODIMENTS

The technical solutions in the embodiments of the present disclosure will be clearly and completely described below with reference to the accompanying drawings in the embodiments of the present disclosure.

In the illustration of some embodiments of the present disclosure, it should be noted that orientation or positional relationships indicated by terms such as “inner”, “outer”, etc. are orientation or positional relationships based on those as shown in the drawings, or based on orientation or positional relationships of a product of some embodiments of the present disclosure which is conventionally placed during use, and are only used to facilitate the illustration of some embodiments of the present disclosure and to simplify the illustration, rather than indicating or implying that an apparatus or element referred to must have a specific orientation, and be constructed and operated in the specific orientation, and therefore said terms cannot be understood as limiting some embodiments of the present disclosure. In addition, the terms “first”, “second” and the like are used for distinguished illustration only and cannot be construed as indicating or implying relative importance.

It should also be noted that unless specified and limited otherwise, the terms “provide” and “connect” should be understood broadly, and for example, can be fixed connection, and can also be detachable connection, or integral connection; can be direct connection, and can also be indirect connection by means of an intermediate medium, and can also be interior communication between two elements. For a person of ordinary skill in the art, specific meanings of the described terms in some embodiments of the present disclosure could be understood according to specific situations.

Resonators currently applied to the radio frequency market include Surface Acoustic Wave Resonators (SAWRs) and Bulk Acoustic Wave Resonators (BAWRs), wherein the BAWRs have gradually become the mainstream of the market due to the advantages of high resonance frequency, high quality factor, high electromechanical coupling coefficient, high power capacity, low loss, small volume, and compatibility with CMOS semiconductor technology.

The BAWRs can be classified into two types: Solidly Mounted Resonators (SMRs) and Film Bulk Acoustic Resonators (FBARs). In some embodiments of the present disclosure, FBAR is taken as an example, and the same applies to SMR. A film bulk acoustic wave has a typical sandwich-structured FBAR, comprising: an upper electrode-piezoelectric layer-lower electrode sandwich structure in a working area, and a silicon substrate and a cavity structure. In addition, a lower electrode lead-out hole and a gold protection layer are further included. A working principle of the FBAR is: a radio frequency electrical signal is applied by an upper electrode and a lower electrode, and the electrical signal is converted into high-frequency vibration of a film by utilizing an inverse piezoelectric effect of a piezoelectric material, so as to generate an acoustic wave signal. In the related art, the Q value cannot be further increased.

In order to solve the described problem, embodiments of the present disclosure provide a film bulk acoustic resonator (hereinafter simply referred to as a resonator) and a manufacturing method therefor, which effectively increases the Q value of the resonator by changing the structure of a lower electrode.

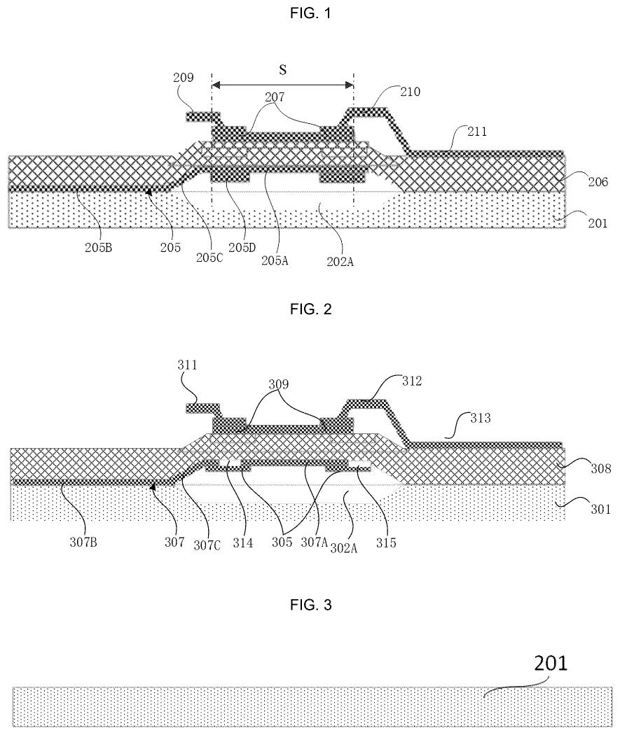

Specifically, referring to FIGS. 1 and 2, embodiments of the present disclosure provide a film bulk acoustic resonator, comprising: a substrate, and a lower electrode, a piezoelectric layer, electrode frame layers and an upper electrode sequentially stacked on the substrate; wherein a cavity is formed between the substrate and the lower electrode, a Q-increasing structure is formed by the lower electrode in a vertical projection range of the cavity, and a first air wing and a first air bridge are formed between the upper electrode and the piezoelectric layer.

In some embodiments, the substrate is a silicon substrate, and in some embodiments, the substrate can also be prepared by using one of ordinary high-resistance, low-resistance, polycrystalline and amorphous silicon wafer materials; and the cavity is formed on one side of the substrate.

The lower electrode is stacked on the substrate, and the lower electrode does not completely cover the substrate. For example, the lower electrode extends to the position of the cavity, and the Q-increasing structure is also formed in the vertical projection range of the lower electrode on the cavity. By means of the Q-increasing structure, the Q value of the resonator can be increased.

The piezoelectric layer is formed on the lower electrode, the piezoelectric layer completely covers the lower electrode and the substrate, and the piezoelectric layer forms a protrusion at a position corresponding to the cavity, for example, the protrusion is a trapezoid protrusion, and corresponds to the position of the cavity. The cavity can be considered as a hexagonal cavity shape consisting of two symmetrical trapezoids.

Further, a protrusion is also formed at a position of the lower electrode corresponding to the cavity, so that the lower electrode forms a layered structure having a height difference, and the Q-increasing structure is located at the position of the protrusion of the lower electrode.

Two electrode frame layers are formed on the piezoelectric layer, and the electrode frame layers are located on the protrusion of the piezoelectric layer; the upper electrode is formed on the electrode frame layers, the upper electrode does not completely cover the piezoelectric layer, and the upper electrode forms a first air bridge between the position of one electrode frame layer and the piezoelectric layer, and the upper electrode forms a first air wing between the position of the other electrode frame layer and the piezoelectric layer; and the first air wing and the first air bridge both correspond to the protrusion of the piezoelectric layer, and by arranging the first air bridge and the first air wing, the object of increasing the Q value is achieved.

Thus, in the film bulk acoustic resonator provided in the embodiments of the present disclosure, the lower electrode, the piezoelectric layer, the electrode frame layers and the upper electrode are sequentially stacked on the substrate; wherein the cavity is formed between the substrate and the lower electrode, the Q-increasing structure is formed within the vertical projection range of the lower electrode on the cavity, the first air wing and the first air bridge are formed between the upper electrode and the piezoelectric layer, and the first air wing and the first air bridge can increase the Q-value of the resonator. Moreover, in some embodiments of the present disclosure, by forming the Q-increasing structure on the lower electrode, the structure of the lower electrode is changed, and the Q value of the resonator is further effectively increased.

Specifically, in some embodiments of the present disclosure, there are two implementation methods for the Q-increasing structure of the lower electrode. In one implementation, as shown in FIG. 1, the Q-increasing structure includes thickened layers 205D of the lower electrode 205, and the thickened layers are on a side of close to the cavity 202A.

In FIG. 1, the lower electrode 205 extends from the left side of a substrate 201 to the position of the cavity 202A of the substrate 201, and the lower electrode 205 includes a first electrode area 205A and a second electrode area 205B; in the stacking direction, the first electrode area 205A is higher than the second electrode area 205B, and the first electrode area 205A and the second electrode area 205B are connected by a transition electrode area 205C to form a height difference. The transition electrode area 205C and the first electrode area 205A are both located at the position of the cavity 202A, and the thickened layers 205D are located on the first area 205A and protrude towards the direction of the cavity 202A. Exemplarily, there are two thickened layers 205D in some embodiments of the present disclosure.

In some embodiments, in a plan view, each of the thickened layers 205D is a continuous annular structure, and in some other embodiments, each of the thickened layers 205D is a discontinuous block structure. The width of the thickened layers 205D is related to the electromechanical coupling coefficient of the resonator, and the height of the thickened layers 205D is related to the frequency and Q value of the resonator.

Positions of the thickened layers 205D and electrode frame layers 207 of an upper electrode 211 are as follows: the width of the thickened layers 205D of the lower electrode 205 can be the same as that of the electrode frame layers 207 of the upper electrode 211, and can also be wider/narrower than that of the electrode frame layers 207 of the upper electrode 211. For example, if an area enclosed boundaries where the upper electrode 211 and the lower electrode 205 contact a piezoelectric layer 206 is taken as an active area S, then the outer boundaries of the electrode frame layers 207 of the upper electrode 211 are outer boundaries of the active area S, and the outer boundaries of the thickened layers 205D of the lower electrode 205 can exceed the active area S.

In another implementation, as shown in FIG. 2, the Q-increasing structure includes a second air wing 315 and a second air bridge 314 which are formed between a lower electrode 307 and a piezoelectric layer 308, wherein the second air wing 315 corresponds to a first air bridge 312, and the second air bridge 314 corresponds to a first air wing 311. Such staggered distribution is to prevent parasitic capacitance from being formed between an upper electrode 313 and the lower electrode 307, thereby affecting the performance of the resonator. More detailed illustration is: an air portion of the second air bridge 314 is located right below a thickened position of the piezoelectric layer 308, and in this way, the upper electrode 313 is thickened to increase the Q value by reducing spurious modes through frequency dispersion characteristics; and the lower electrode 307 reflects transverse acoustic waves by using a large difference between air and a solid acoustic impedance through the air portion, thereby reducing energy leakage, and further increasing the Q value.

In addition, in some embodiments, the air portions of the upper electrode 313 and the lower electrode 307 are filled with a dielectric material. In this way, the materials at these positions do not need to be additionally released to form the air portions. It should be noted that compared with forming the air portions, the effect of increasing the Q-value by filling the dielectric material is not better than that by forming the air portions.

Likewise, the lower electrode 307 has a first electrode area 307A and a second electrode area 307B connected by a transition electrode area 307C to form a layered structure having a height difference; the transition electrode area 307C and the first electrode area 307A are both located at the position of a cavity 302A, and the second air wing 315 and the second air bridge 314 are located at the first electrode area 307A.

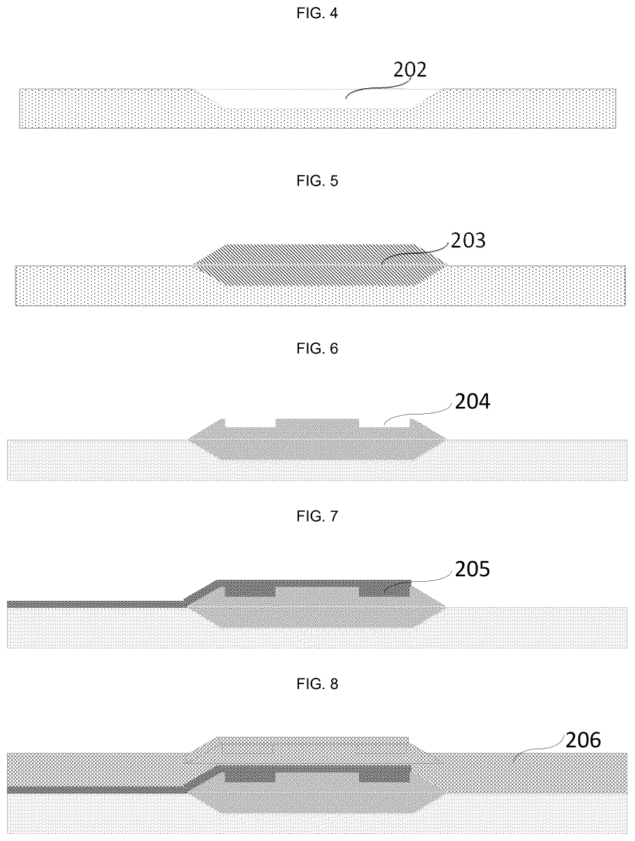

On this basis, embodiments of the present disclosure further disclose a manufacturing method for a film bulk acoustic resonator, which is used for manufacturing the film bulk acoustic resonator according to any one above. For embodiments in which a thickened layer is used as a Q-increasing structure, the method includes:
S100: a substrate 201 is provided, and the substrate 201 is etched to form a cavity 202A, as shown in FIGS. 3 and 4.
the substrate 201 is etched to form a first cavity structure 202, as shown in FIG. 4.

A first sacrificial layer 203 is filled in the first cavity structure 202, wherein the first sacrificial layer 203 can be flush with the surface of the substrate 201, and can also be higher than the surface of the substrate 201; exemplarily, in FIG. 5, the first sacrificial layer 203 protrudes from the surface of the substrate 201.

Two second cavity structures 204 are etched in the first sacrificial layer 203, as shown in FIG. 6. Exemplarily, the two second cavity structures 204 are etched at the protruding first sacrificial layer 203, and the etching depth of the two second cavity structures 204 does not reach the top surface of the substrate 201.

In addition, the second cavity structures 204 are not limited to be etched at one side of the first sacrificial layer 203, and can be etched at two sides of the first sacrificial layer 203, and can also be etched at multiple sides of the first sacrificial layer 203.

In FIG. 6, positions of the first sacrificial layer 203 except the second cavity structures 204 form the cavity 202A of a subsequent finished product as shown in FIG. 1.

S110: a lower electrode 205 is deposited on the substrate 201 provided with the cavity 202A, so that the lower electrode 205 covers a part of the substrate 201, and a Q-increasing structure is formed in a vertical projection range of the lower electrode 205 on the cavity 202A.

As shown in FIG. 7, the lower electrode 205 is deposited on the substrate 201 provided with the second cavity structures 204, the lower electrode 205 covers one end of the substrate 201 up to the second cavity structures 204, and fills the second cavity structures 204, so as to form thickened layers 205D within the second cavity structures 204.

In FIG. 7, the lower electrode 205 covers the left side up to the right side of the substrate 201, until extending into the first sacrificial layer 203 and filling in the two second cavity structures 204. The materials of the lower electrode 205 filled into the two second cavity structures 204 form the thickened layers 205D in FIG. 1.

The material of the lower electrode 205 is a metal material, comprising common molybdenum (Mo), gold (Au), aluminum (Al), copper (Cu), titanium (Ti), tungsten (W), etc.

S120: a piezoelectric layer 206, electrode frame layers 207, and an upper electrode 211 are sequentially formed on the lower electrode 205, so as to form a first air bridge 210 and a first air wing 209 on the upper electrode 211.

In FIG. 8, the piezoelectric layer 206 is deposited on the lower electrode 205, and the piezoelectric layer 206 contains various piezoelectric materials, comprising AlN, PZT, ZnO, LiNbO₃, LiTaO₃, etc., so that the piezoelectric layer 206 completely covers the lower electrode 205 and the substrate 201, and the piezoelectric layer 206 protrudes at the position corresponding to the first cavity structure 202. Exemplarily, the piezoelectric layer 206 forms a protruding trapezoid structure at the first cavity structure 202.

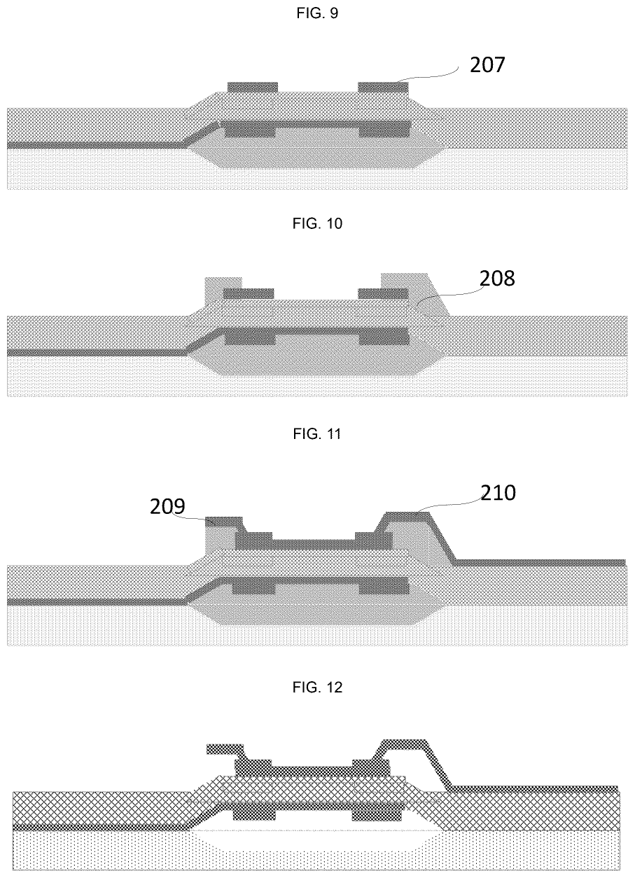

As shown in FIG. 9, electrode frame layers 207 are deposited at positions of the protruding piezoelectric layer 206 which correspond to the second cavity structures 204. Exemplarily, there are two electrode frame layers 207, which correspond to the two second cavity structures 204, respectively. The electrode frame layers 207 can be the same as or different from the metal layer of the upper electrode 211.

In FIG. 10, upper electrode second sacrificial layers 208 are deposited at positions corresponding to the electrode frame layers 207, so that the upper electrode second sacrificial layers 208 cover a part of the electrode frame layers 207 and a part of the piezoelectric layer 206 adjacent to the electrode frame layers 207.

In FIG. 11, the upper electrode 211 is deposited on the piezoelectric layer 206, so that the upper electrode 211 covers the other end (right end) of the piezoelectric layer 206 up to the protruding piezoelectric layer 206, the upper electrode second sacrificial layers 208, and the electrode frame layers 207.

The upper electrode 211 starts covering from the right end of the piezoelectric layer 206 and extends sequentially through the upper electrode second sacrificial layer 208 on the right side, the electrode frame layer 207 on the right side, the protruding piezoelectric layer 206, the electrode frame layer 207 on the left side, and the upper electrode sacrificial layer 208 on the left side, so as to form the first air wing 209 and the first air bridge 210 at the positions of the two upper electrode sacrificial layers 208 respectively.

S130: the first sacrificial layer 203 and the upper electrode second sacrificial layers 208 are released, the cavity 202A is formed on the substrate 201, the Q-increasing structure is formed on the lower electrode 205, and the first air bridge 210 and the first air wing 209 are formed on the upper electrode 211.

The first sacrificial layer 203 is released to form the cavity 202A at the substrate 201, meanwhile the lower electrode 205 is displayed as thickened layers 205D of the Q-increasing structure.

The upper electrode second sacrificial layers 208 are released, to form the first air bridge 210 and the first air wing 209 between the upper electrode 211 and the piezoelectric layer 206, so as to obtain the structural diagrams of the resonator as shown in FIGS. 1 and 12.

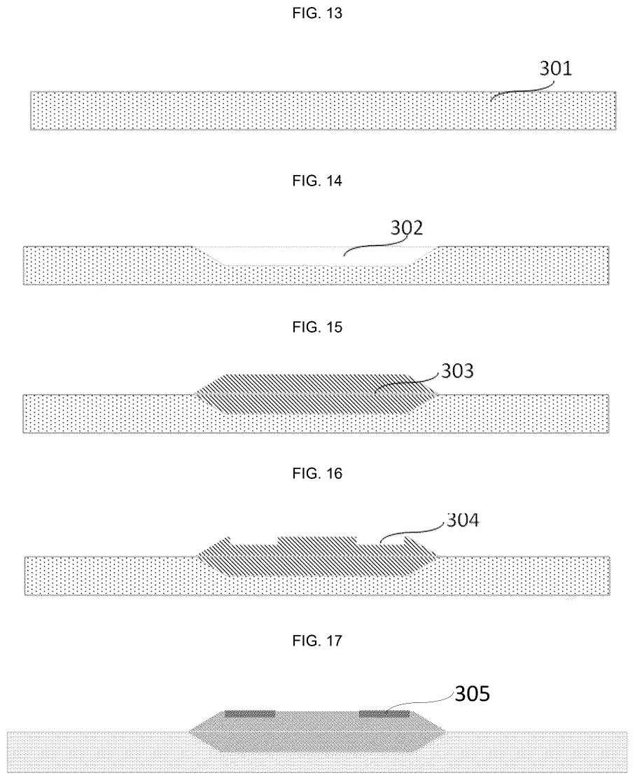

In another aspect, for embodiments in which a second air bridge 314 and a second air wing 315 are taken as a Q-increasing structure, a manufacturing method for a film bulk acoustic resonator according to embodiments of the present disclosure includes:
S200: a substrate 301 is provided, and the substrate 301 is etched to form a cavity 302A, as shown in FIGS. 13 and 14.

The substrate 301 is etched is etched to form a first cavity structure 302, as shown in FIG. 14. The shape of the first cavity structure 302 can not be limited, and an inverted trapezoid-shaped first cavity structure 302 is illustrated in FIG. 14.

A first sacrificial layer 303 is filled in the first cavity structure 302, wherein the first sacrificial layer 303 can be flush with the surface of the substrate 301, and it can also be the case that the first sacrificial layer 303 is higher than the surface of the substrate 301 as shown in FIG. 15.

Two second cavity structures 304 are etched in the first sacrificial layer 303, as shown in FIG. 16. Exemplarily, the two second cavity structures 304 are etched at the protruding first sacrificial layer 303, and the etching depth of the two second cavity structures 304 does not reach the top surface of the substrate 301.

In FIG. 16, the shape of the first sacrificial layer 303 except the second cavity structures 304 form the cavity 302A in FIG. 2.

The second cavity structures 304 are not limited to be etched at one side of the first sacrificial layer 303, and can be etched at two sides of the first sacrificial layer 303, and can also be etched at multiple sides of the first sacrificial layer 303.

S210: a lower electrode 307 is deposited on the substrate 301 provided with the cavity 302A, so that the lower electrode 307 covers a part of the substrate 301, and a Q-increasing structure is formed in a vertical projection range of the lower electrode 307 on the cavity 302A.

As shown in FIG. 17, the second cavity structures 304 are filled with Q-increasing materials 305, such that the Q-increasing materials 305 fill the second cavity structures 304 flush.

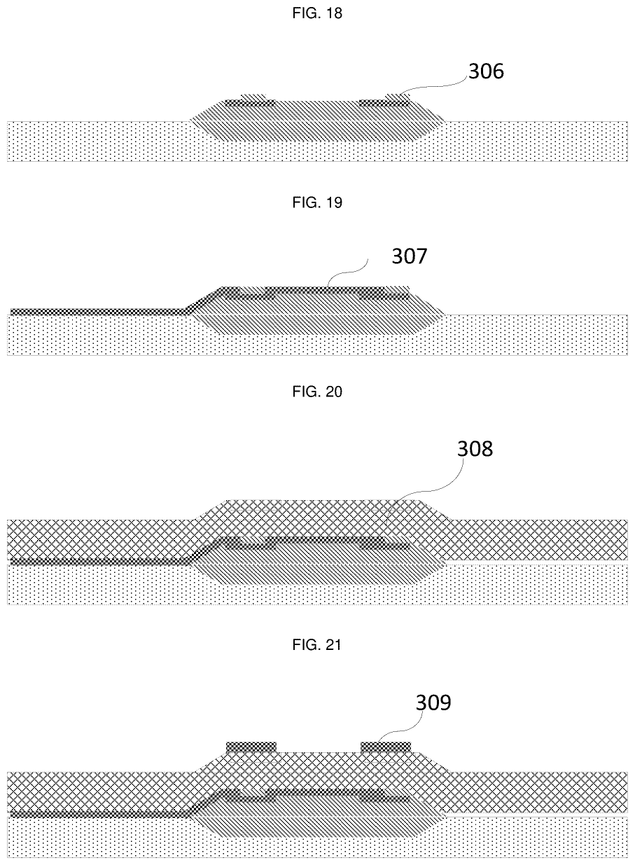

In FIG. 18, upper electrode first sacrificial layers 306 are deposited on the Q-increasing materials 305 to form a second air wing 315 and a second air bridge 314 at the upper electrode first sacrificial layers 306.

In FIG. 19, the lower electrode 307 is deposited on the substrate 301, and the material of the lower electrode 307 is a metal material, comprising common molybdenum (Mo), gold (Au), aluminum (Al), copper (Cu), titanium (Ti), tungsten (Wu), etc. The lower electrode 307 covers one end of the substrate 301 up to the first sacrificial layer 303, and exposes the upper electrode first sacrificial layers 306; and the surface of the lower electrode 307 at the first sacrificial layer 303 is flush with the surfaces of the upper electrode first sacrificial layers 306.

S220: a piezoelectric layer 308, electrode frame layers 309, and an upper electrode 313 are sequentially formed on the lower electrode 307, so as to form a first air bridge 312 and a first air wing 311 on the upper electrode 313.

In FIG. 20, the piezoelectric layer 308 is deposited on the lower electrode 307, so that the piezoelectric layer 308 completely covers the lower electrode 307 and the substrate 301, and the piezoelectric layer 308 protrudes at the position corresponding to the first cavity structure 302, so as to form a protruding trapezoid structure.

The piezoelectric layer 308 contains various piezoelectric materials, comprising AlN, PZT, ZnO, LiNbO₃, LiTaO₃, etc.

As shown in FIG. 21, electrode frame layers 309 are deposited at positions of the protruding piezoelectric layer 308 which correspond to the second cavity structures 304. In FIG. 21, there are two electrode frame layers 309, which correspond to the two second cavity structures 304, respectively. The electrode frame layers 309 can be the same as or different from the metal layer of the upper electrode 313.

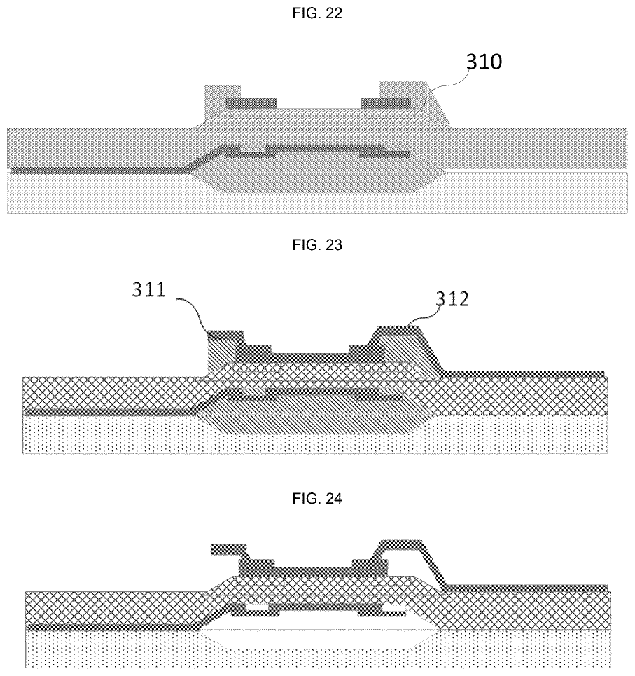

In FIG. 22, upper electrode second sacrificial layers 310 are deposited at positions corresponding to the electrode frame layers 309, so that the upper electrode second sacrificial layers 310 cover a part of the electrode frame layers 309 and a part of the piezoelectric layer 308 adjacent to the electrode frame layers 309.

In FIG. 23, the upper electrode 313 is deposited on the piezoelectric layer 308, so that the upper electrode 313 covers the other end (right end) of the piezoelectric layer 308 up to the protruding piezoelectric layer 308, the upper electrode second sacrificial layers 310, and the electrode frame layers 309, to form the first air wing 311 and the first air bridge 312.

The upper electrode 313 starts covering from the right end of the piezoelectric layer 308 and extends sequentially through the upper electrode second sacrificial layer 310 on the right side, the electrode frame layer 309 on the right side, the protruding piezoelectric layer 308, the electrode frame layer 309 on the left side, and the upper electrode sacrificial layer 310 on the left side.

S230: the first sacrificial layer 303, the upper electrode first sacrificial layers 306 and the upper electrode second sacrificial layers 310 are released, the cavity 302A is formed on the substrate 301, the Q-increasing structure is formed on the lower electrode 307, and the first air bridge 312 and the first air wing 311 are formed on the upper electrode 313.

The first sacrificial layer 303 is released to form the cavity 302A of FIG. 2 at the substrate 301.

The upper electrode first sacrificial layers 306 are released, to form the second air bridge 314 and the second air wing 315 between the lower electrode 307 and the piezoelectric layer 308.

The upper electrode second sacrificial layers 310 are released, to form the first air bridge 312 and the first air wing 311 between the upper electrode 313 and the piezoelectric layer 308, so as to obtain the structural diagrams of the resonator as shown in FIGS. 2 and 24.

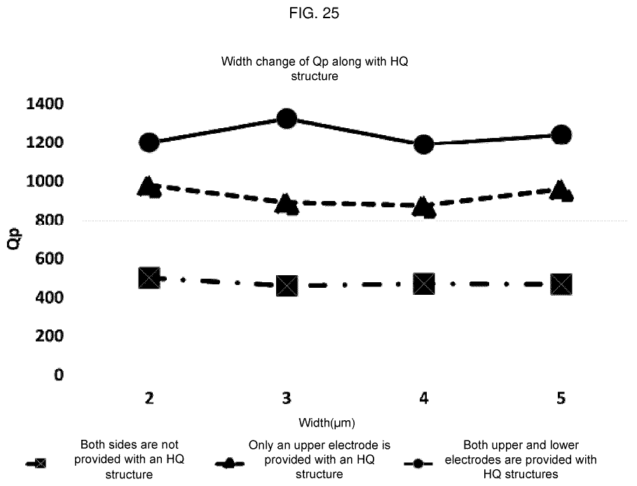

FIG. 25 compares simulation curves of resonators in which an upper electrode and a lower electrode are not provided with an HQ structure, only an upper electrode is provided with an HQ structure, and both an upper electrode and a lower electrode are provided with HQ structures. Upon comparison, it can be clearly determined that the effect obtained by both the upper electrode and the lower electrode being provided with HQ structures is better than the effect obtained by only the upper electrode being provided with an HQ structure, which is better than the effect obtained by the upper electrode and the lower electrode being not provided with an HQ structure.

The manufacturing method for a film bulk acoustic resonator includes the same structure and beneficial effects as those of the film bulk acoustic resonator in the embodiments above. The structure and beneficial effects of the film bulk acoustic resonator have been described in detail in the embodiments above, and will not be repeated herein.

The content above merely relates to embodiments of the present disclosure, and is not intended to limit the scope of protection of the present disclosure. For a person skilled in the art, some embodiments of the present disclosure can have various modifications and changes. Any modifications, equivalent replacements, improvements and the like made within the spirit and principle of the present disclosure shall all fall within the scope of protection of the present disclosure.

What is claimed is:

1. A film bulk acoustic resonator comprising:
a substrate, and
a lower electrode, a piezoelectric layer, electrode frame layers and an upper electrode sequentially stacked on the substrate;
wherein a cavity is formed between the substrate and the lower electrode, a Q-increasing structure is formed by the lower electrode in a vertical projection range of the cavity, and a first air wing and a first air bridge are formed between the upper electrode and the piezoelectric layer.

2. The film bulk acoustic resonator according to claim 1, wherein the Q-increasing structure comprises at least one thickened layer of the lower electrode, and the at least one thickened layer is on a side of close to the cavity.

3. The film bulk acoustic resonator according to claim 1, wherein the lower electrode has a first electrode area and a second electrode area connected by a transition electrode area to form a layered structure having a height difference; the transition electrode area and the first electrode area are both located at a position of the cavity.

4. The film bulk acoustic resonator according to claim 3, wherein the at least one thickened layer is located on a surface of the first electrode area and protrudes towards a direction of the cavity.

5. The film bulk acoustic resonator according to claim 4, wherein there are two thickened layers, which are located at the first electrode area at an interval.

6. The film bulk acoustic resonator according to claim 4, wherein the at least one thickened layer is continuous annular structures or discontinuous block structures.

7. The film bulk acoustic resonator according to claim 4, wherein a width of the at least one thickened layer is the same as or different from a width of the electrode frame layer.

8. The film bulk acoustic resonator according to claim 1, wherein the Q-increasing structure comprises a second air wing and a second air bridge formed between the lower electrode and the piezoelectric layer, wherein in a stacking direction, the second air wing corresponds to the first air bridge, and the second air bridge corresponds to the first air wing; and the second air wing and the second air bridge are located at the first electrode area.

9. The film bulk acoustic resonator according to claim 1, wherein the lower electrode at a position corresponding to the cavity and the piezoelectric layer at a position corresponding to the cavity form a protrusion, and the electrode frame layers are located on the protrusion of the piezoelectric layer; and the first air wing and the first air bridge both correspond to the protrusion of the piezoelectric layer, and the Q-increasing structure is located on the protrusion of the lower electrode.

10. The film bulk acoustic resonator according to claim 1, wherein the lower electrode does not completely cover the substrate; and the upper electrode does not completely cover the piezoelectric layer.

11. The film bulk acoustic resonator according to claim 1, wherein the protrusion is a trapezoid protrusion.

12. The film bulk acoustic resonator according to claim 1, wherein an area enclosed by projection boundaries of the upper electrode, the lower electrode and the piezoelectric layer is an active area, and outer boundaries of the thickened layers exceed the active area.

13. The film bulk acoustic resonator according to claim 1, wherein there are two electrode frame layers, the upper electrode at a position of one electrode frame layer and the piezoelectric layer form the first air bridge, and the upper electrode at a position of the other electrode frame layer and the piezoelectric layer form the first air wing.

14. The film bulk acoustic resonator according to claim 1, wherein a material of the lower electrode comprises at least one of Mo, Au, Al, Cu, Ti and Wu, and the piezoelectric layer comprises at least one of AlN, PZT, ZnO, LiNbO₃ and LiTaO₃.

15. A manufacturing method for a film bulk acoustic resonator, the method being used for manufacturing the film bulk acoustic resonator according to claim 1, wherein the method comprises:
providing a substrate, and etching the substrate to form a cavity;
depositing a lower electrode on the substrate provided with the cavity, so that the lower electrode covers a part of the substrate, and forming a Q-increasing structure in a vertical projection range of the lower electrode on the cavity; and
sequentially forming a piezoelectric layer, at least one electrode frame layer and an upper electrode on the lower electrode, so as to form a first air bridge and a first air wing between the upper electrode and the piezoelectric layer.

16. The manufacturing method for a film bulk acoustic resonator according to claim 15, wherein providing the substrate, and etching the substrate to form the cavity, comprise:
etching the substrate to form a first cavity structure;
filling a first sacrificial layer in the first cavity structure; and
etching the first sacrificial layer to form two second cavity structures.

17. The manufacturing method for a film bulk acoustic resonator according to claim 16, wherein depositing the lower electrode on the substrate provided with the cavity, so that the lower electrode covers the part of the substrate, and forming the Q-increasing structure in the vertical projection range of the lower electrode on the cavity, comprise:
depositing the lower electrode on the substrate provided with the second cavity structures, so that the lower electrode covers one end of the substrate up to the second cavity structures, and fills the second cavity structures, so as to form at least one thickened layer in at least one of the second cavity structures.

18. The manufacturing method for a film bulk acoustic resonator according to claim 16, wherein depositing the lower electrode on the substrate provided with the cavity, so that the lower electrode covers the part of the substrate, and forming the Q-increasing structure in the vertical projection range of the lower electrode on the cavity, comprise:
filling the second cavity structures with Q-increasing materials, so that the Q-increasing materials fill the second cavity structures flush;
depositing upper electrode first sacrificial layers on the Q-increasing materials to form a second air wing and a second air bridge at the upper electrode first sacrificial layers; and
depositing the lower electrode on the substrate, so that the lower electrode covers one end of the substrate up to the first sacrificial layer, and exposing the upper electrode first sacrificial layers.

19. The manufacturing method for a film bulk acoustic resonator according to claim 17, wherein sequentially forming the piezoelectric layer, the at least one electrode frame layer and the upper electrode on the lower electrode, so as to form a first air bridge and a first air wing between the upper electrode and the piezoelectric layer, comprises:
depositing the piezoelectric layer on the lower electrode, so that the piezoelectric layer completely covers the lower electrode and the substrate, and the piezoelectric layer protrudes at a position corresponding to the first cavity structure;
depositing the electrode frame layers at positions of the protruding piezoelectric layer which correspond to the second cavity structures;
depositing upper electrode second sacrificial layers at positions corresponding to the electrode frame layers, so that the upper electrode second sacrificial layers cover a part of the electrode frame layers and a part of the piezoelectric layer adjacent to the electrode frame layers; and
depositing the upper electrode on the piezoelectric layer, so that the upper electrode covers an other end of the piezoelectric layer up to the protruding piezoelectric layer, the upper electrode second sacrificial layers, and the electrode frame layers.

20. The manufacturing method for a film bulk acoustic resonator according to claim 19, wherein sequentially forming the piezoelectric layer, the at least one electrode frame layer and the upper electrode on the lower electrode, so as to form a first air bridge and a first air wing between the upper electrode and the piezoelectric layer, the method further comprises:
releasing the first sacrificial layer, the upper electrode first sacrificial layers, and the upper electrode second sacrificial layers.
